(19) United States
(12) Patent Application Publication
(10) Pub. No.: US 2026/0333673 A1
(43) Pub. Date: Oct. 22, 2026

(54) THREE-DIMENSIONAL STACKED DRAM DEVICE WITH 3.5F2 STRUCTURE CELLS

(71) Applicant: TAESUNG ENVIRONMENTAL RESEARCH INSTITUTE CO., LTD., Ulsan (KR)

(72) Inventors: Gi Yeol Yun, Ulsan (KR); Seok Man Kim, Ulsan (KR); Chai Rok Lim, Ulsan (KR); Hyeok-Je Jeong, Gimhae-si (KR); Myung-Kon Jo, Ulsan (KR)

(73) Assignee: TAESUNG ENVIRONMENTAL RESEARCH INSTITUTE CO., LTD., Ulsan (KR)

(21) Appl. No.: 19/401,934

(22) Filed: Nov. 26, 2025

(30) Foreign Application Priority Data
Apr. 17, 2025 (KR) 10-2025-0050483

(51) Int. Cl. H10B 12/00

(52) U.S. Cl. CPC H10B 12/482; H10B 12/488

(57) ABSTRACT

A three-dimensional stacked DRAM device including a substrate; a plurality of first conductive lines oriented in a first direction perpendicular to an upper surface of the substrate; a plurality of second conductive lines oriented in a second direction perpendicular to the first conductive lines; a plurality of channel patterns arranged in a honeycomb structure on the second conductive lines; and a gate insulating pattern disposed between the plurality of channel patterns and the plurality of first conductive lines, wherein the plurality of first conductive lines include first sub-lines and second sub-lines having different distances from the second conductive lines, wherein a plurality of channel patterns contacting a single first conductive line are arranged in a straight line, and a plurality of channel patterns positioned on a single second conductive line are arranged in a zigzag along both side edges of the single second conductive line.

### CROSS-REFERENCE TO RELATED APPLICATION

This application claims priority to and the benefit of Korean Patent Application No. 10-2025-0050483, filed on Apr. 17, 2025, the disclosure of which is incorporated herein by reference in its entirety.

### BACKGROUND

### 1. Field of the Invention

The present invention relates to a DRAM device, and more particularly, to a 3D stacked DRAM device using c cell of a 3.5F2 structure (an example of sub-4F2 structure).

### 2. Discussion of Related Art

A DRAM cell has a 1T1C (one transistor-one capacitor) structure that stores and reads data, and is composed of a capacitor and a transistor (Non-Patent Document 1).

In a DRAM cell, the capacitor stores charge to preserve logical information, and the transistor is controlled to turn on/off by a word line to provide a data path between the capacitor and a bit line. The bit line is a data transmission path, and the word line serves as a signal line that activates or deactivates the transistor as the gate of the transistor. In this configuration, the operation of the DRAM cell is divided into writing, reading, and refreshing, and weak signal amplification and periodic data recharging are performed through a Sense Amplifier and Refresh Circuitry, among others.

Meanwhile, the main operating processes of a DRAM cell can be divided into a Write Operation, a Read Operation, and a Refresh Operation. The write operation is an operation for storing data, where the word line is activated to turn on the access transistor, input data is transmitted to the capacitor through the bit line (positive charge is stored in the capacitor for logic ‘1’, and negative charge is stored in the capacitor for logic ‘0’), the word line is deactivated to turn off the access transistor, and the data is stored in the capacitor. The read operation is an operation for reading data, where the word line is activated to turn on the access transistor, the charge state of the capacitor is transmitted to the bit line (if there is positive charge in the capacitor, a slight voltage rise is detected in the bit line, and if there is negative charge in the capacitor, a slight voltage drop is detected in the bit line), and the data on the bit line is amplified by a Sense Amplifier and converted into a readable signal.

Since the capacitor of a DRAM undergoes natural discharge over time, it needs to be periodically refreshed to avoid losing data, which is called the refresh operation. The refresh cycle is generally in units of several milliseconds (ms), and it replenishes the charge by reading the cell data and then writing the same data back.

Key characteristics of a DRAM cell include: it is a volatile memory where data is lost as the capacitor's charge discharges when power is cut off; its simple 1T1C structure allows for high integration density, fast access, and operation with low power; and it requires a periodic refresh cycle to maintain data, which consumes additional power.

Major considerations during DRAM cell operation include: as DRAM cells are miniaturized, the capacitor capacitance decreases, making it difficult to store sufficient charge, which can reduce data stability; interference (coupling noise) may occur between adjacent bit lines; and a sufficient margin (sensing margin) is needed to distinguish signals from noise during a read operation. Through these operations, the DRAM cell stores, reads, and maintains data, performing its role as a high-density and high-performance memory.

As the integration density of semiconductor memory devices has increased, the cell structure has been continuously scaled down from 8F² and 6F² to 4F² to reduce the area occupied by each unit memory cell in a planar manner. Correspondingly, various technologies have been proposed to implement components such as transistors, bit lines, word lines, and capacitors within the 4F² cell structure.

In particular, as one method for reducing the unit cell area, DRAM devices including vertical channel transistors, which induce a vertical channel by arranging source and drain regions vertically, have been studied. Chung et al. proposed a new 4F² DRAM cell structure applying a vertical pillar transistor (VPT) (Non-Patent Document 2). It was expected that using such vertical channel transistors could enhance cell area efficiency.

However, in the vertical channel DRAM device according to the prior art (Non-Patent Document 2), the vertical pillar and the cell capacitor are in direct contact, causing a problem where leakage current flows during data storage. As a result, the charge stored in the capacitor is quickly depleted, shortening the retention time, which requires frequent refresh operations and increases power consumption.

Meanwhile, efforts are continuously being made to reduce the minimum feature size (F) and implement smaller cell layouts to further improve the integration density of memory devices. However, due to the limitations of fine process technology, physical limits are appearing in increasing capacity per unit area. That is, due to the limitations of the minimum feature size defined by the level of manufacturing process technology such as photolithography, it is difficult to achieve additional improvements in integration density with the conventional 4F² cell structure alone.

To overcome these limitations of the 2D planar structure, 3D-structured DRAM devices, in which memory cells are stacked and arranged three-dimensionally, are being proposed. In a 3D stacked DRAM device, cell transistors and wirings are stacked vertically, which can increase the memory capacity per unit area. However, as the number of layers increases, problems such as transistor driving stability, interference between wirings, and signal delay may occur. Therefore, continuous research is required on new cell designs and wiring structures in 3D structures.

The present invention originates from this background and aims to improve retention characteristics and reliability by improving the structure of a 3D stacked DRAM device that includes vertical channel transistors.

(Non-Patent Literature 1) Robert H. Dennard, “Operation of a One-Transistor Cell Used in a High-Density DRAM”, IEEE Journal of Solid-State Circuits, Vol. SC-9, No. 5, Oct. 1974

(Non-Patent Literature 2) Chung et al., “4F2 DRAM Cell with Vertical Pillar Transistor (VPT)”, 2011 Proceedings of the European Solid-State Device Research Conference (ESSDERC), 2011

### SUMMARY OF THE INVENTION

One of the various objects of the present invention is to provide a vertical channel transistor that can improve the retention time of a cell transistor, and a DRAM device including the same.

Another object of the present invention is to provide a 3D stacked DRAM device that can increase the storage capacity per unit area.

Furthermore, another object of the present invention is to provide a DRAM device that can enhance operational reliability by stabilizing transistor driving and improving signal transfer efficiency through a new wiring structure in which word lines are stably contacted with the substrate.

According to one aspect, a three-dimensional (3D) stacked DRAM device to which 3.5F2 structure cells are applied is provided, the device comprising: a substrate; a plurality of first conductive lines oriented in a first direction perpendicular to an upper surface of the substrate, and arranged parallel to each other at a predetermined interval; a plurality of second conductive lines oriented in a second direction perpendicular to the first conductive lines, and arranged parallel to each other at a predetermined interval; a plurality of channel patterns arranged in a honeycomb structure on the second conductive lines, and each extending in a third direction perpendicular to both the first direction and the second direction; and a gate insulating pattern disposed between the plurality of channel patterns and the plurality of first conductive lines, wherein the plurality of first conductive lines include first sub-lines and second sub-lines having different distances from the second conductive lines, and the first and second sub-lines are alternately arranged with each other in the second direction, wherein a plurality of channel patterns contacting a single first conductive line are arranged in a straight line, and a plurality of channel patterns positioned on a single second conductive line are arranged in a zigzag along both side edges of the single second conductive line.

In one embodiment, the device may further comprise a gate electrode disposed between the first conductive line and the gate insulating pattern.

According to another aspect, a 3D stacked DRAM device to which 3.5F2 structure cells are applied is provided, the device comprising: a substrate; a plurality of first and third conductive lines oriented in a first direction perpendicular to an upper surface of the substrate, and arranged parallel to each other at a predetermined interval; a plurality of second conductive lines oriented in a second direction perpendicular to the first and third conductive lines, and arranged parallel to each other at a predetermined interval; a plurality of first and second channel patterns arranged in a honeycomb structure on the second conductive lines, each extending in a third direction perpendicular to both the first direction and the second direction, and connected to the first and third conductive lines, respectively; and a gate insulating pattern disposed between the plurality of first and second channel patterns and the plurality of first and third conductive lines, wherein the plurality of first conductive lines include first sub-lines and second sub-lines having different distances from the second conductive lines, and the first and second sub-lines are alternately arranged with each other in the second direction, wherein the plurality of third conductive lines include third sub-lines and fourth sub-lines having different distances from the second conductive lines, and the third and fourth sub-lines are alternately arranged with each other in the second direction, wherein a plurality of the first and second channel patterns contacting a single first or third conductive line are arranged in a straight line, and a plurality of the first and second channel patterns positioned on a single second conductive line are arranged in a zigzag along both side edges of the single second conductive line.

In one embodiment, the device may further comprise a gate electrode disposed between the first conductive line or the third conductive line and the gate insulating pattern.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a perspective view of a vertical channel transistor according to an embodiment of the present invention.

FIG. 2 is a cross-sectional view taken along line A-A′ of FIG. 1.

FIG. 3 is a cross-sectional view taken along line B-B′ of FIG. 1.

FIG. 4 is a plan view of the vertical channel transistor of FIG. 1, viewed from the xz plane.

FIG. 5 is a perspective view of a DRAM device including the vertical channel transistor of FIG. 1.

FIG. 6 is a diagram illustrating the structure of a vertical channel transistor according to a first modified example.

FIG. 7A is a plan view of a DRAM device including a conventional 4F2 structure vertical channel transistor, and FIG. 7B is a plan view of a DRAM device including a vertical channel transistor in which the spacing between adjacent word lines or bit lines is reduced by half.

### DETAILED DESCRIPTION OF EXEMPLARY EMBODIMENTS

Hereinafter, exemplary embodiments will be described in detail with reference to the accompanying drawings. However, the descriptions herein may be embodied in many different forms and should not be construed as limited to the embodiments set forth herein.

Throughout the specification, when a part is “connected” to another part, this includes not only “directly connected” cases but also “indirectly connected” cases with other members interposed between them. Also, when a member is described as being “on”, “above”, “on top of”, “under”, “below”, or “at the bottom of” another member, this includes not only cases where the member is in contact with the other member but also cases where another member exists between the two members.

Throughout this specification, when a part “comprises” or “includes” a certain component, it means that it can further include other components, not excluding other components, unless otherwise specified.

The embodiments described in this specification will be explained with reference to perspective views, cross-sectional views, etc., which are ideal exemplary diagrams of the present invention. Also, throughout the specification, the same reference numerals denote the same constituent elements. At this time, detailed descriptions of known functions and configurations that could obscure the gist of the present invention have been omitted.

And, in each drawing illustrated in the present invention, each constituent element may be somewhat exaggerated or reduced for convenience of explanation. Furthermore, the embodiments of the present invention are not limited to the specific forms shown, but also include changes in form that may be generated according to the manufacturing process.

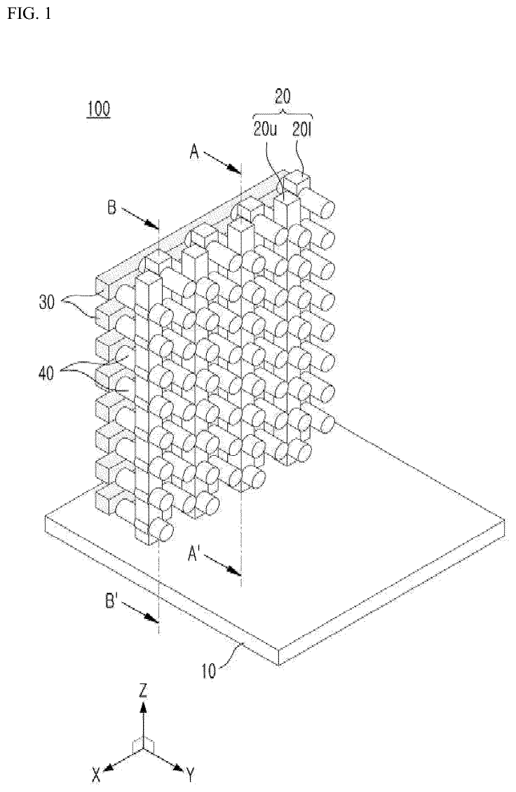

FIG. 1 is a perspective view schematically illustrating a vertical channel transistor according to an embodiment of the present invention. Referring to FIG. 1, the vertical channel transistor (100) according to an embodiment of the present invention includes: a substrate (10); a plurality of first conductive lines (20) oriented in a first direction (e.g., z-axis direction) perpendicular to the upper surface of the substrate (10), and arranged parallel to each other at a predetermined interval; a plurality of second conductive lines (30) oriented in a second direction (e.g., x-axis direction) perpendicular to the first conductive lines, and arranged parallel to each other at a predetermined interval; a plurality of channel patterns (40) arranged in a honeycomb structure on the second conductive lines (30), and each extending in a third direction (y-direction) perpendicular to both the first direction and the second direction; and a gate insulating pattern (not shown) disposed between the plurality of channel patterns (40) and the plurality of first conductive lines (20).

The plurality of first conductive lines (20) include first sub-lines (20u) and second sub-lines (20l) having different distances from the second conductive lines (30), and the first and second sub-lines (20u and 20l) are alternately arranged with each other in the second direction. A plurality of channel patterns (40) contacting a single first conductive line (20) are arranged in a straight line, and a plurality of channel patterns (40) positioned on a single second conductive line (30) are arranged in a zigzag along both side edges of the single second conductive line.

Preferably, the first conductive line (20) may be a word line, and the second conductive line (30) may be a bit line, but it is not limited thereto. That is, the roles of the first and second conductive lines may be changed as needed.

In the vertical channel transistor (100) according to an embodiment of the present invention, the plurality of first conductive lines (20u and 20l) and the plurality of second conductive lines (30) are arranged to intersect each other. Each of the first conductive lines (20u and 20l) may be provided to extend in the first direction (e.g., z-axis direction) perpendicular to the substrate (10), and each of the second conductive lines (30) may be provided to extend in the second direction (e.g., x-axis direction) intersecting the first direction.

A plurality of channel patterns (40) are disposed at the intersections of the plurality of first conductive lines (20u and 20l) and the plurality of second conductive lines (30). Electrodes (not shown) are formed on the top and bottom of the plurality of channel patterns (40), respectively. The region between the upper electrode (40u) and the lower electrode (40l) is a body region (not shown), which has the same polarity as the substrate (10), while the upper electrode (40u) and the lower electrode (40l) have a different polarity from the substrate (10). For example, if the substrate (10) is a p-type semiconductor substrate, the body region has p-type polarity, and the upper electrode (40u) and the lower electrode (40l) have n-type polarity. In this case, the upper electrode (40u) and the lower electrode (40l) can be formed by implanting n-type impurity ions into the top and bottom of the channel pattern (40), respectively, and performing drive-in diffusion.

A gate (50) is formed to surround the side of the channel pattern (40) between the upper electrode and the lower electrode, and the gate (50) may be composed of a gate insulating pattern (52) and a gate conductive pattern (54).

The plurality of first conductive lines (20u and 20l) include the first sub-lines (20u) and the second sub-lines (20l) having different distances from the second conductive lines (30), and the first and second sub-lines are alternately arranged with each other in the second direction (e.g., x-axis direction). In conventional vertical channel transistors, the plurality of word lines are arranged side-by-side at substantially the same height, posing a physical limitation in increasing the capacity per unit area.

However, in the present invention, adjacent word lines are disposed at different heights, which allows the minimum feature size (F) to be easily reduced. As a result, there is an advantage in that capacity per unit area can be increased and integration density can be improved. In addition, the present inventors, through repeated research, have found that by orienting the word lines perpendicular to the substrate (stacking them vertically) and stacking the bit lines in 3D parallel to the substrate, and by alternately arranging the word lines at different distances from the bit lines, the integration density can be more effectively improved. At the same time, they confirmed that the electrical contact between the word lines and the substrate increases the driving stability of the device and improves signal transfer efficiency, leading to the completion of the present invention.

The first and second sub-lines (20u and 20l) may be independently formed of at least one material from metals, semiconductors, and alloys. They may be formed of the same material or different materials from each other. Spacers (not shown) may be provided on the sidewalls of the first and second sub-lines (20u and 20l), and the spacers can serve to prevent contact with other channel patterns (40) that are not interconnected by the first and second sub-lines (20u and 20l).

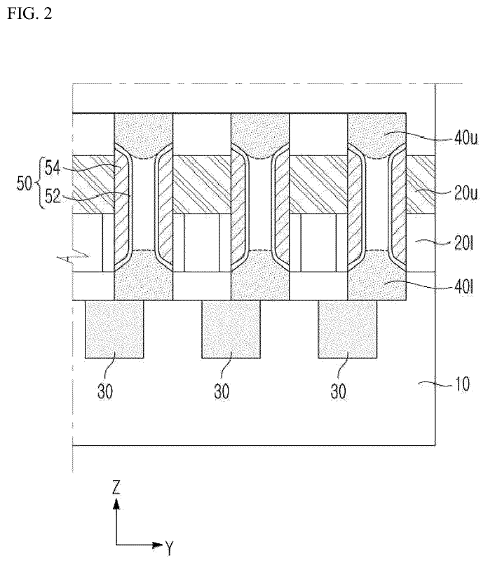

FIG. 2 is a cross-sectional view taken along line A-A′ of FIG. 1. The substrate (10) may include, for example, a Group IV semiconductor material such as silicon (Si), germanium (Ge), silicon germanium (SiGe), or silicon carbide (SiC), a Group III-V semiconductor material such as gallium arsenide (GaAs), indium arsenide (InAs), or indium phosphide (InP), an oxide semiconductor, a nitride semiconductor, or an oxynitride semiconductor. Specifically, the substrate may be a silicon substrate doped with n-type impurities, but is not limited thereto.

Each of the plurality of channel patterns (40) may be provided to extend in a direction parallel to the substrate (10). Here, one end of each channel pattern (40) contacts the second conductive line (30) and may be provided in a third direction (e.g., y-axis direction) that is parallel to the upper surface of the substrate (10) and perpendicular to both the first direction and the second direction. Each channel pattern (40) may include the same semiconductor material as the substrate (10).

Each of the plurality of channel patterns (40) may include a source region as an upper electrode (40u) and a drain region as a lower electrode (40l). The lower electrode (40l) is electrically connected to the second conductive line (30), and the upper electrode (40u) may be electrically connected to a capacitor (not shown), which will be described later. The positions of the source region and the drain region may be changed as needed. For example, the upper electrode (40u) may function as a drain region, and the lower electrode (40l) may function as a source region.

In the channel pattern (40), the region between the upper electrode (40u) and the lower electrode (40l) is a body region (not shown), which has the same polarity as the substrate (10), while the upper electrode (40u) and the lower electrode (40l) have a different polarity from the substrate (10). For example, if the substrate (10) is a p-type semiconductor substrate, the body region has p-type polarity, and the upper electrode (40u) and the lower electrode (40l) have n-type polarity. In this case, the upper electrode (40u) and the lower electrode (40l) can be formed by implanting n-type impurity ions into the top and bottom of the channel pattern (40), respectively, and performing drive-in diffusion.

A gate (50) is formed to surround the side of the channel pattern (40) between the upper electrode and the lower electrode, and the gate (50) may be composed of a gate insulating pattern (52) and a gate conductive pattern (54).

The second conductive line (30) is provided to extend along the first direction (e.g., z-axis direction) below the lower electrode (40l), and each second conductive line (30) can electrically connect the lower electrodes (40l) arranged along the first direction. The second conductive line (30) may include the same semiconductor material as the substrate (10).

Each of the plurality of first sub-lines (20u) is provided at a position corresponding to the upper part of the gate (50) formed on the side of the channel pattern (40). Furthermore, each first sub-line (20u) is provided to surround at least a part of the upper part of the gate (50). The first sub-line (20u) may include a conductive material. For example, the first sub-line (20u) may include at least one or more selected from metals, semiconductors, and alloys. Specifically, the first sub-line (20u) may include at least one metal selected from the group consisting of aluminum, tungsten, molybdenum, titanium, and tantalum, or at least one semiconductor selected from the group consisting of Group IV semiconductors, Group III-V semiconductors, oxide semiconductors, nitride semiconductors, and oxynitride semiconductors, but is not limited thereto.

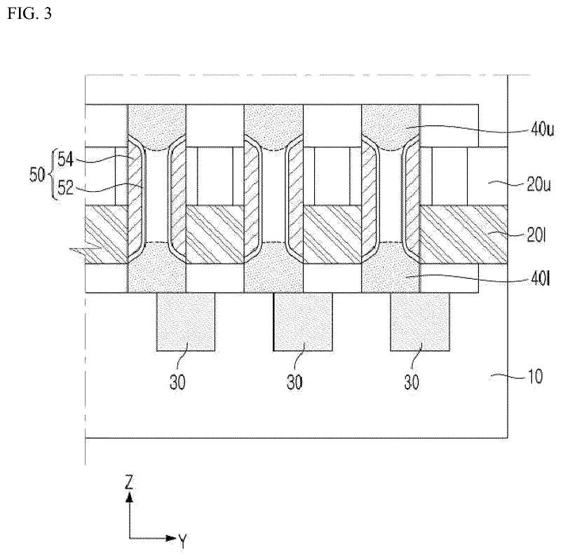

FIG. 3 is a cross-sectional view taken along line B-B′ of FIG. 1. Referring to FIG. 3, the plurality of channel patterns (40) are commonly connected to the second sub-line (20l). Specifically, each second sub-line (20l) is provided at a height corresponding to the lower part of the gate (50) formed on the side of the channel pattern (40). Also, each first sub-line (20u) is provided to surround at least a part of the lower part of the gate (50). Translator's Note: Source [125] appears to mistakenly refer to “first sub-line (20u)” when “second sub-line (20l)” is contextually correct based on [124]. The translation follows the source, but this may be an error in the original document.

When viewed in a cross-section of the yz plane, the second sub-line (20l) is disposed at a different height from the first sub-line (20u). Specifically, the second sub-line (20l) is disposed at a lower position than the first sub-line (20u). By arranging the adjacent first and second sub-lines (20u and 20l) at different heights in this way, the minimum feature size (F) can be easily reduced, and as a result, there is an advantage in that capacity per unit area can be increased and integration density can be improved.

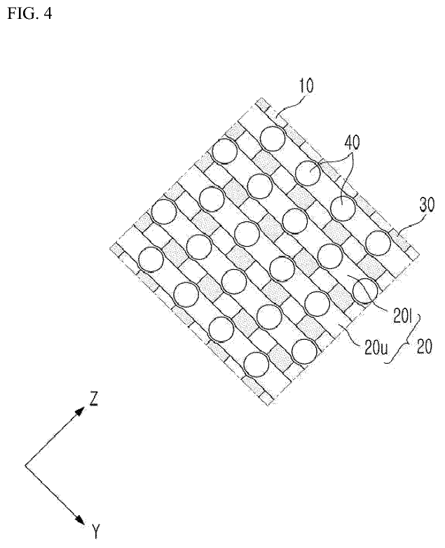

FIG. 4 is a plan view of the vertical channel transistor of FIG. 1, with respect to the xz plane. Referring to FIG. 4, the plurality of channel patterns (40) are arranged in a honeycomb structure on the second conductive line (30). Here, the honeycomb structure refers to a structure where channel patterns are placed at the center point and the six vertices of a hexagon, such that each channel pattern located at the six vertices becomes the center point of each of the 6 neighboring hexagons. In the honeycomb structure, the hexagon may be a regular hexagon, and the 6 triangles sharing the center point may all be equilateral triangles.

In this way, by arranging the plurality of channel patterns (40) in a honeycomb structure, a 3.5F2 structure can be achieved without adjusting the width of the first conductive lines (20l and 20u), the width of the second conductive line (30), and the spacing between adjacent second conductive lines (30). For example, when the diameter of each channel pattern (40), the width of the first conductive lines (20l and 20u), the width of the second conductive line (30), and the spacing between adjacent first conductive lines (20l and 20u) are all equal to F, the area of the parallelogram connecting four channel patterns is about 3.464F² (=2F×2Fsin60°). Translator's Note: The premise “all equal to F” and the calculation “3.464F2” in source [132] are contradictory. The translation follows the source.

Consequently, there is an advantage in that the 3.5F2 structure can be easily achieved without increasing the bit line-to-bit line capacitance, bit line-to-word line capacitance, and bit line-to-substrate capacitance, that is, while maintaining the ratio of bit line capacitance (Cb) to cell capacitance (Cs) at the same level as conventional ones.

As the plurality of channel patterns (40) have a honeycomb structure, the plurality of channel patterns (40) contacting a single first conductive line (20u and 20l) are arranged in a straight line, and the plurality of channel patterns (40) positioned on a single second conductive line (30) are arranged in a zigzag along both side edges of the single second conductive line (30). When the diameter of each channel pattern (40), the width of the second conductive line (30), and the spacing between adjacent second conductive lines (30) are all equal to F, the inner half of each channel pattern (40) is located on the second conductive line (30).

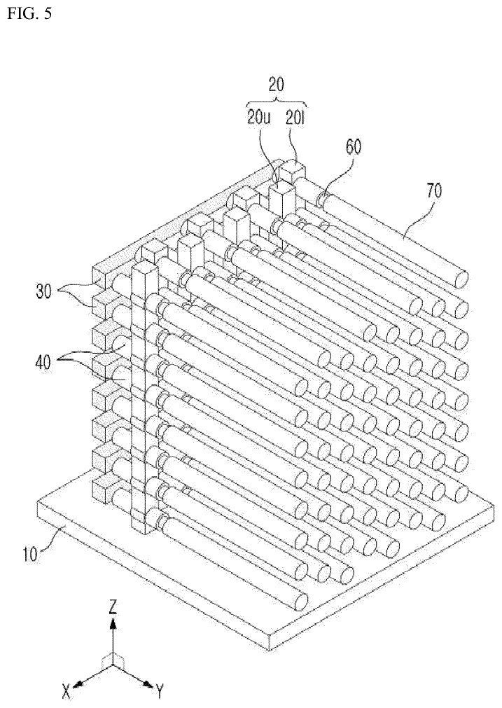

FIG. 5 is a perspective view schematically illustrating a DRAM device including the vertical channel transistor of FIG. 1. Referring to FIG. 5, by electrically connecting a capacitor (70) to the vertical channel transistor (100), a DRAM device (200), for example, can be implemented. The capacitor (70) may be electrically connected to the channel pattern (40), and a contact plug (60) may be further interposed between the capacitor (70) and the channel pattern (40). Through this, the DRAM device (200) utilizing the vertical channel transistor (100) as a memory cell is constructed. Such a vertical channel transistor (100) is versatile enough to be applicable not only to the memory devices described above but also to transistors in non-memory devices such as a central processing unit (CPU).

### First Modified Example

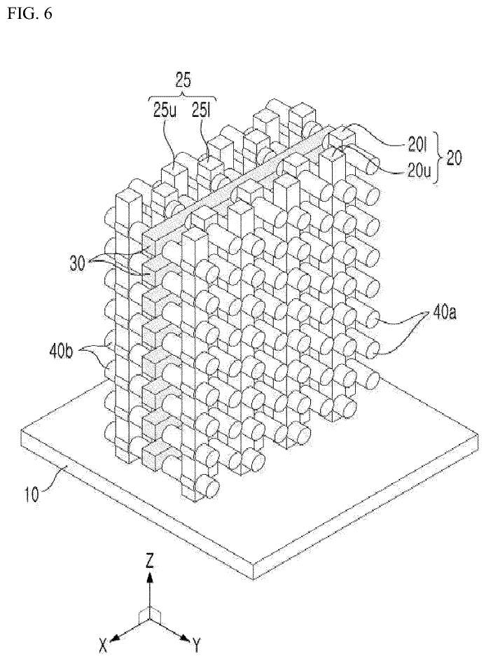

FIG. 6 is a cross-sectional view of a vertical channel transistor according to a first modified example. In FIG. 6, components that are the same as in the embodiment described above are given the same reference numerals, and descriptions thereof are omitted or simplified.

In the first modified example, two channel patterns (40), namely a first channel pattern (40a) and a second channel pattern (40b), are configured to be connected to one second conductive line (30). One of the first and second channel patterns (40a, 40b) is connected to the first conductive line (20), and the other is connected to a third conductive line (25). Both the first and third conductive lines function as word lines.

Furthermore, the third conductive line (25), like the first conductive line (20), is formed vertically to contact the substrate (10), thereby forming a bidirectional word line structure (a structure where the second conductive line and the third conductive line face each other in parallel) with the bit line (30) in between.

The plurality of first conductive lines (20) include first sub-lines (20u) and second sub-lines (20l) having different distances from the second conductive lines (30), and the first and second sub-lines are alternately arranged with each other in the second direction. The plurality of third conductive lines (25) include third sub-lines (25u) and fourth sub-lines (25l) having different distances from the second conductive lines (30), and the third and fourth sub-lines are alternately arranged with each other in the second direction.

The bidirectional 3D stacked DRAM device thus formed has an advantage in that channel patterns or capacitors can be formed on both sides, unlike conventional transistors where they can only be formed on one side. Along with that, the floating phenomenon can be prevented, and a high integration density can be secured even in a smaller substrate area with a reduced minimum feature size.

Hereinafter, the technical reason why the minimum feature size F can be easily reduced because adjacent word lines are disposed at different heights from the bit line will be described in more detail.

In the field of DRAM devices, the minimum feature size F is an important factor that determines the integration density and performance of the device. The minimum feature size F means the smallest line width that can be drawn in a semiconductor circuit, and is generally the smallest of (1) the width of the word line, (2) the width of the bit line, (3) the spacing between adjacent word lines, and (4) the spacing between adjacent bit lines. The smaller the minimum feature size F, the higher the transistor density of the semiconductor chip, the smaller the chip size, and the lower the power consumption. Therefore, technological development in the DRAM device field is moving in the direction of adopting the smallest possible minimum feature size F.

However, this minimum feature size cannot be reduced indefinitely and is usually determined by the level of technological development at the time of manufacturing. Specifically, it is determined by the resolution of photolithography equipment and the quality and performance of the photoresist.

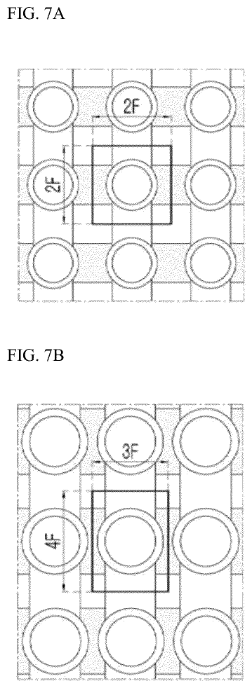

FIG. 7A is a plan view of a DRAM device including a conventional 4F2 structure vertical channel transistor. In FIG. 7A, (1) the width of the word line, (2) the width of the bit line, (3) the spacing between adjacent word lines, and (4) the spacing between adjacent bit lines are all set to F, thus having a 4F2 structure.

FIG. 7B is a plan view of a DRAM device including a vertical channel transistor, manufactured by reducing (3) the spacing between adjacent word lines to half (½) compared to (1) the width of the word line, (2) the width of the bit line, and (4) the spacing between adjacent bit lines. In this case, (3) the spacing between adjacent word lines becomes the minimum feature size F. Since this minimum feature size F is determined by the level of technological development at the time of manufacturing, it ultimately results in an increase in the unit cell area (12F2=4F×3F). That is, adjusting the spacing between adjacent word lines to reduce the unit cell area is by no means desirable.

However, in the present invention, as long as the spacing between adjacent first word lines and the spacing between adjacent second word lines are each equal to or greater than the minimum feature size F, the horizontal spacing between an adjacent first word line and second word line can be adjusted arbitrarily. This is because word lines formed on different planes (different heights) are formed in different process steps, so they are not affected by the minimum feature size determined by the level of technology at the time of manufacturing. Theoretically, the horizontal spacing between an adjacent first word line and second word line can be adjusted down to ½F.

Therefore, the DRAM device according to an aspect of the present invention has the advantage of achieving an improved capacity per unit area compared to the capacity per unit area generally achievable at the level of technological advancement at the time of manufacturing.

The DRAM device according to an aspect of the present invention has the advantage of suppressed leakage current generation and long retention time. In addition, the DRAM device according to an aspect of the present invention has advantages of excellent data retention characteristics and low power consumption. The 3D stacked DRAM device according to an aspect of the present invention has the effect of suppressing leakage current generation in the cell transistor and increasing the retention time. Furthermore, the DRAM device according to an aspect of the present invention has excellent data retention characteristics, allowing stable operation without frequent refresh operations, and as a result, has the advantage of reducing power consumption. Moreover, the DRAM device according to an aspect of the present invention can significantly increase the capacity per unit area through a 3D cell arrangement and has the advantage of improving high integration density by overcoming ultra-fine process limitations by forming adjacent wirings in a multi-layered structure. In particular, by adopting a structure where the word line is in direct contact with the substrate, the electrical stability of the gate line is increased, and the signal transmission path is shortened, which stabilizes transistor driving and improves signal transfer efficiency. As a result, the operational reliability of the DRAM device is greatly enhanced. The effects of one aspect of the present invention are not limited to the effects described above, and should be understood to include all effects that can be inferred from the configurations described in the detailed description or claims of this specification.

The foregoing description in this specification is for illustrative purposes, and those of ordinary skill in the art to which this aspect of the specification pertains will be able to understand that easy modifications into other specific forms are possible without changing the technical spirit or essential features described in this specification. Therefore, the embodiments described above should be understood as exemplary in all respects and not restrictive. For example, each component described as a single unit may be implemented in a distributed manner, and likewise, components described as distributed may be implemented in a combined form. The scope of this specification is indicated by the claims described below, and all changes or modified forms derived from the meaning and scope of the claims and their equivalent concepts should be interpreted as being included in the scope of this specification.

What is claimed is:

1. A three-dimensional (3D) stacked DRAM device to which 3.5F2 structure cells are applied, the device comprising:
a substrate;
a plurality of first conductive lines oriented in a first direction perpendicular to an upper surface of the substrate, and arranged parallel to each other at a predetermined interval;
a plurality of second conductive lines oriented in a second direction perpendicular to the first conductive lines, and arranged parallel to each other at a predetermined interval;
a plurality of channel patterns arranged in a honeycomb structure on the second conductive lines, and each extending in a third direction perpendicular to both the first direction and the second direction; and
a gate insulating pattern disposed between the plurality of channel patterns and the plurality of first conductive lines,
wherein the plurality of first conductive lines include first sub-lines and second sub-lines having different distances from the second conductive lines, and the first and second sub-lines are alternately arranged with each other in the second direction,
wherein a plurality of channel patterns contacting a single first conductive line are arranged in a straight line, and a plurality of channel patterns positioned on a single second conductive line are arranged in a zigzag along both side edges of the single second conductive line.

2. The 3D stacked DRAM device of claim 1, further comprising a gate electrode disposed between the first conductive line and the gate insulating pattern.

3. A 3D stacked DRAM device to which 3.5F2 structure cells are applied, the device comprising:
a substrate;
a plurality of first and third conductive lines oriented in a first direction perpendicular to an upper surface of the substrate, and arranged parallel to each other at a predetermined interval;
a plurality of second conductive lines oriented in a second direction perpendicular to the first and third conductive lines, and arranged parallel to each other at a predetermined interval;
a plurality of first and second channel patterns arranged in a honeycomb structure on the second conductive lines, each extending in a third direction perpendicular to both the first direction and the second direction, and connected to the first and third conductive lines, respectively; and
a gate insulating pattern disposed between the plurality of first and second channel patterns and the plurality of first and third conductive lines,
wherein the plurality of first conductive lines include first sub-lines and second sub-lines having different distances from the second conductive lines, and the first and second sub-lines are alternately arranged with each other in the second direction,
wherein the plurality of third conductive lines include third sub-lines and fourth sub-lines having different distances from the second conductive lines, and the third and fourth sub-lines are alternately arranged with each other in the second direction, and
wherein a plurality of the first and second channel patterns contacting a single first or third conductive line are arranged in a straight line, and a plurality of the first and second channel patterns positioned on a single second conductive line are arranged in a zigzag along both side edges of the single second conductive line.

4. The 3D stacked DRAM device of claim 3, further comprising a gate electrode disposed between the first conductive line or the third conductive line and the gate insulating pattern.
